(19) United States
(12) Patent Application Publication
(10) Pub. No.: US 2025/0169323 A1
(43) Pub. Date: May 22, 2025

(54) DISPLAY DEVICE

(71) Applicant: LG Display Co., Ltd., Seoul (KR)

(72) Inventors: SeongHun JEONG, Paju-si (KR); Hyunguk JANG, Paju-si (KR); Haye KIM, Paju-si (KR)

(73) Assignee: LG Display Co., Ltd., Seoul (KR)

(21) Appl. No.: 18/784,519

(22) Filed: Jul. 25, 2024

(30) Foreign Application Priority Data
Nov. 21, 2023 (KR) 10-2023-0162258

(51) Int. Cl. H10K 59/40; H10K 59/122; H10K 59/35; H10K 59/38; H10K 59/80

(52) U.S. Cl. CPC H10K 59/40; H10K 59/122; H10K 59/351; H10K 59/353; H10K 59/38; H10K 59/8792

(57) ABSTRACT

A display device which simultaneously secures a viewing angle and a touch sensing performance is discussed. The display device can include a light emitting device layer having a first light emitting area, a second light emitting area disposed adjacent to the first light emitting area and extending in a first direction, a third light emitting area disposed adjacent to the first light emitting area and extending in a second direction, and a fourth light emitting area disposed adjacent to the third light emitting area and extending in the first direction. The display device can further include an encapsulation layer covering the light emitting device layer, a touch electrode having a mesh structure non-overlapping the first to fourth light emitting areas, and a black matrix including opening portions overlapping the first to fourth light emitting areas.

### CROSS-REFERENCE TO RELATED APPLICATIONS

This application claims priority to Korean Patent Application No. 10-2023-0162258 filed in the Republic of Korea on Nov. 21, 2023, the entire contents of which is hereby expressly incorporated by reference into the present application.

### BACKGROUND

### Field of the Invention

The present disclosure relates to a display device, and more particularly, to a display device having a touch sensing function.

### Discussion of the Related Art

As the information society develops, the demand for display devices which display images is increasing. As a result, various types of display devices such as liquid crystal displays and organic light emitting displays are being used.

In order to provide a user with more various functions, the display device can recognize the user's touch on the display panel and perform input processing based on the recognized touch. For example, a plurality of touch electrodes can be disposed in an active area of the display panel. In addition, the display device can sense a touch by sensing a change in the capacitance of the touch electrode caused by the user's touch.

### SUMMARY OF THE DISCLOSURE

Accordingly, the present disclosure is directed to providing a display device that substantially obviates one or more problems due to limitations and disadvantages of the related art.

An aspect of the present disclosure is directed to providing a display device which simultaneously secures a viewing angle and a touch sensing performance.

Additional advantages and features of the disclosure will be set forth in part in the description which follows and in part will become apparent to those having ordinary skill in the art upon examination of the following or can be learned from practice of the disclosure. The objectives and other advantages of the disclosure can be realized and attained by the structure particularly pointed out in the written description as well as the appended drawings.

To achieve these and other advantages and in accordance with the purpose of the disclosure, as embodied and broadly described herein, there is provided a display device which can comprises a light emitting device layer including a first light emitting area, a second light emitting area adjacent to the first light emitting area in a first direction, a third light emitting area adjacent to the first light emitting area in a second direction, and a fourth light emitting area adjacent to the third light emitting area in the first direction; an encapsulation layer covering the light emitting device layer; a touch electrode disposed on the encapsulation layer and having a mesh structure non-overlapping the first to fourth light emitting areas; a black matrix including opening portions overlapping the first to fourth light emitting areas, disposed on the touch electrode, and covering the entire touch electrode; and color filters filled in each of the opening portions and having a larger area than each of the first to fourth light emitting areas. An average width of a first portion of the touch electrode extending in the second direction between the first light emitting area and the second light emitting area can be different from an average width of a second portion of the touch electrode extending in the first direction between the first light emitting area and the third light emitting area.

According to an embodiment of the present disclosure, the first light emitting area emits a first color of light, the second light emitting area emits a second color of light, and the third light emitting area and the fourth light emitting area can emit a third color of light.

According to an embodiment of the present disclosure, each of the first to fourth light emitting areas can have a circular shape in a plan view.

According to an embodiment of the present disclosure, a distance between the first light emitting area and the second light emitting area is shorter than a distance between the first light emitting area and the third light emitting area, the first portion has a first width, and the second portion can have a second width greater than the first width.

According to an embodiment of the present disclosure, the touch electrode further includes a third portion which extends in the second direction from an intersection of the first portion and the second portion, and is adjacent to the fourth light emitting area, and a width of the third portion can be greater than the second width.

According to an embodiment of the present disclosure, the first to fourth light emitting areas configure a pixel, and a distance between a fourth light emitting area of a first pixel and a third light emitting area of a second pixel adjacent to the first pixel in the first direction can be greater than a distance between the first light emitting area and the third light emitting area in the second direction.

According to an embodiment of the present disclosure, a portion of the black matrix non-overlapping with the touch electrode has a circular ring shape in a plan view, and the circular ring shape can have a uniform width.

According to an embodiment of the present disclosure, a width of the first portion of the touch electrode in the first direction and a width of the second portion of the touch electrode in the second direction can be variable.

According to an embodiment of the present disclosure, a minimum width of the first portion of the touch electrode can be different from a minimum width of the second portion of the touch electrode.

According to an embodiment of the present disclosure, the touch electrode further includes a third portion disposed between the third light emitting area and the fourth light emitting area and having a variable width in the first direction, and a minimum width of the third portion can be different from the minimum width of the first portion and the minimum width of the second portion.

According to an embodiment of the present disclosure, the light emitting device layer includes first electrodes corresponding to the first to fourth light emitting areas, each of the first electrodes having a circular shape in a plan view, a bank covering a portion of the first electrodes and disposed between the first electrodes, a light emitting layer disposed on the first electrodes, and a second electrode disposed on the light emitting layer, wherein the bank can be black.

According to an embodiment of the present disclosure, each of the color filters can have a circular shape in a plan view.

According to an embodiment of the present disclosure, the display device can further comprise a protective layer disposed between the touch electrode and the black matrix.

According to an embodiment of the present disclosure, the protective layer is in direct contact with the touch electrode, the black matrix, and the color filters, and the protective layer can include an inorganic insulating material.

According to an embodiment of the present disclosure, each of the color filters can cover a portion of the black matrix.

According to an embodiment of the present disclosure, an area of a first color filter corresponding to the first light emitting area, an area of a second color filter corresponding to the second light emitting area, and an area of a third color filter corresponding to the third light emitting area can be different from each other.

According to an embodiment of the present disclosure, an area of each of the opening portions of the black matrix can be larger than an area of each of the first to fourth light emitting areas corresponding to the opening portions.

It is to be understood that both the foregoing general description and the following detailed description of the present disclosure are exemplary and explanatory and are intended to provide further explanation of the disclosure as claimed.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain the principle of the disclosure. In the drawings:

FIG. 1 is an exemplary diagram illustrating a display device according to embodiments of the present disclosure;

FIG. 2 is a diagram illustrating an example of a touch electrode included in the display device of FIG. 1 according to an aspect of the present disclosure;

FIG. 3 is a diagram illustrating another example of a touch electrode included in the display device of FIG. 1 according to an aspect of the present disclosure;

FIG. 4 is a diagram for describing an example of a touch sensor included in the display device of FIG. 1 according to an aspect of the present disclosure;

FIG. 5 is a diagram illustrating an example in which the touch sensor of FIG. 4 is implemented according to an aspect of the present disclosure;

FIG. 6 is a plan view illustrating an example of an arrangement of a touch electrode included in the display device of FIG. 1 according to an aspect of the present disclosure;

FIG. 7 is a cross-sectional view illustrating an example of a display device including the touch electrode of FIG. 6 according to an aspect of the present disclosure;

FIG. 8 is a plan view illustrating another example of an arrangement of a touch electrode included in the display device of FIG. 1 according to an aspect of the present disclosure; and

FIG. 9 is a plan view illustrating another example of an arrangement of a touch electrode included in the display device of FIG. 1 according to an aspect of the present disclosure.

### DETAILED DESCRIPTION OF THE EMBODIMENTS

Reference will now be made in detail to the exemplary embodiments of the present disclosure, examples of which are illustrated in the accompanying drawings. Wherever possible, the same reference numbers will be used throughout the drawings to refer to the same or like parts.

Advantages and features of the present disclosure, and implementation methods thereof will be clarified through following embodiments described with reference to the accompanying drawings. The present disclosure can, however, be embodied in different forms and should not be construed as limited to the embodiments set forth herein. Rather, these embodiments are provided so that this disclosure will be thorough and complete, and will fully convey the scope of the present disclosure to those skilled in the art.

A shape, a size, a ratio, an angle, and a number disclosed in the drawings for describing embodiments of the present disclosure are merely an example, and thus, the present disclosure is not limited to the illustrated details. Like reference numerals refer to like elements throughout. In the following description, when the detailed description of the relevant known function or configuration is determined to unnecessarily obscure the important point of the present disclosure, the detailed description will be omitted. When “comprise,” “have,” and “include” described in the present disclosure are used, another part can be added unless “only” is used. The terms of a singular form can include plural forms unless referred to the contrary.

In construing an element, the element is construed as including an error or tolerance range although there is no explicit description of such an error or tolerance range.

In describing a position relationship, for example, when a position relation between two parts is described as, for example, “on,” “above,” “over,” “under,” and “next,” one or more other parts can be disposed between the two parts unless a more limiting term, such as “just” or “direct(ly)” is used.

In describing a time relationship, for example, when the temporal order is described as, for example, “after,” “subsequent,” “next,” and “before,” a case that is not continuous can be included unless a more limiting term, such as “just,” “immediate(ly),” or “direct(ly)” is used.

It will be understood that, although the terms “first,” “second,” etc. can be used herein to describe various elements, these elements should not be limited by these terms. These terms are only used to distinguish one element from another and may not define order or sequence. For example, a first element could be termed a second element, and, similarly, a second element could be termed a first element, without departing from the scope of the present disclosure.

In describing elements of the present disclosure, the terms “first,” “second,” “A,” “B,” “(a),” “(b),” etc. can be used. These terms are intended to identify the corresponding elements from the other elements, and basis, order, or number of the corresponding elements should not be limited by these terms. As for the expression that an element or layer is “connected,” “coupled,” or “adhered” to another element or layer the element or layer can not only be directly connected or adhered to another element or layer, but also be indirectly connected or adhered to another element or layer with one or more intervening elements or layers “disposed,” or “interposed” between the elements or layers, unless otherwise specified.

The term “at least one” should be understood as including any and all combinations of one or more of the associated listed items. For example, the meaning of “at least one of a first item, a second item, and a third item” denotes the combination of all items proposed from two or more of the first item, the second item, and the third item as well as the first item, the second item, or the third item.

Features of various embodiments of the present disclosure can be partially or overall coupled to or combined with each other, and can be variously inter-operated with each other and driven technically as those skilled in the art can sufficiently understand. The embodiments of the present disclosure can be carried out independently from each other, or can be carried out together in co-dependent relationship. Further, the term “can” encompasses all the meanings and coverages of the term “may.”

Hereinafter, embodiments of the present disclosure will be described in detail with reference to the accompanying drawings. All the components of each display device or apparatus according to all embodiments of the present disclosure are operatively coupled and configured.

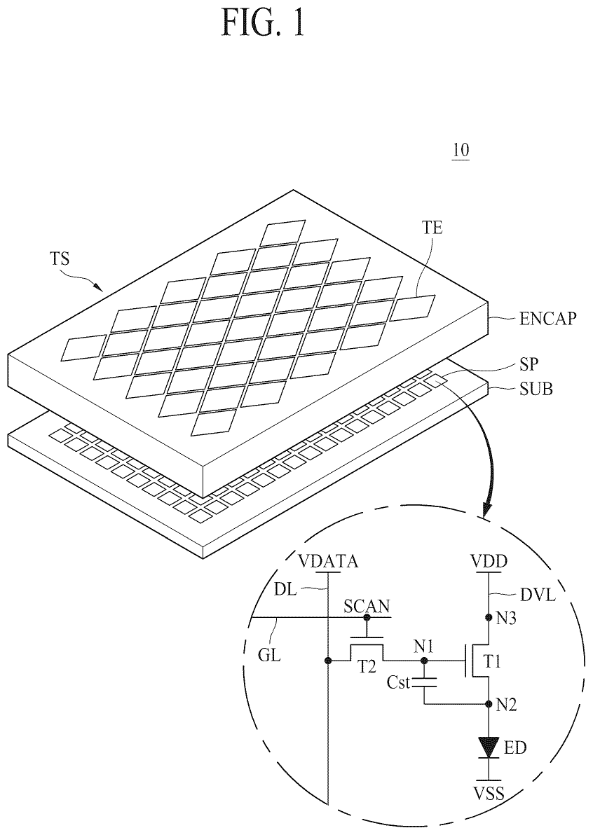

FIG. 1 is an exemplary diagram illustrating a display device according to embodiments of the present disclosure.

Referring to FIG. 1, a display device 10 can include a substrate SUB, sub-pixels SP, an encapsulation layer ENCAP, and a touch sensor TS.

A plurality of sub-pixels SP can be arranged on the substrate SUB. Each sub-pixel SP can include a light emitting device ED, a first transistor T1 for driving the light emitting device ED, a second transistor T2 for transmitting a data voltage VDATA to the first transistor T1, a storage capacitor Cst for maintaining a constant voltage during one frame, and the like.

For example, the first transistor T1 can include a first node N1 to which a data voltage VDATA can be applied, a second node N2 electrically connected to the light emitting device ED, and a third node N3 to which a driving voltage VDD is applied from a driving voltage line DVL. The first node N1 can be a gate node, the second node N2 can be a source node or a drain node, and the third node N3 can be a drain node or a source node. The first transistor T1 is also referred to as a driving transistor to drive the light emitting device ED.

For example, the light emitting device ED can include a first electrode (e.g., an anode electrode), a light emitting layer, and a second electrode (e.g., a cathode electrode). The first electrode can be electrically connected to the second node N2 of the first transistor T1, and a base voltage VSS can be applied to the second electrode.

The light emitting layer can be an organic light emitting layer including an organic material. In this case, the light emitting device ED can be an organic light emitting diode (OLED). However, the light emitting layer can include an inorganic material, and in this case, the light emitting device ED can be an inorganic light emitting device.

For example, the on/off of the second transistor T2 is controlled by a scan signal SCAN applied through a gate line GL, and the second transistor T2 can be electrically connected between the first node N1 of the first transistor T1 and a data line DL. The second transistor T2 is also referred to as a switching transistor.

When the second transistor T2 is turned on by the scan signal SCAN, the data voltage VDATA supplied from the data line DL is transmitted to the first node N1 of the first transistor T1.

The storage capacitor Cst can be electrically connected between the first node N1 and the second node N2 of the first transistor T1.

Each sub-pixel SP can have a 2T1C structure including two transistors T1 and T2 and one capacitor Cst, as illustrated in FIG. 1, and in some cases, can further include one or more transistors or can further include one or more capacitors.

The storage capacitor Cst is not a parasitic capacitor (e.g., Cgs and Cgd), which is an internal capacitor that can exist between the first node N1 and the second node N2 of the first transistor T1, but can be an external capacitor intentionally designed outside the first transistor T1.

For example, each of the first transistor T1 and the second transistor T2 can be an n-type transistor or a p-type transistor.

Each of the sub-pixels SP can emit light of a specific color. For example, the sub-pixel SP can emit one of red, green, blue, and white light.

Also, as described above, circuit elements such as a light emitting device ED, two or more transistors T1 and T2, and one or more capacitors Cst are disposed on the display panel DISP. Because such a circuit element (particularly, the light emitting device ED) is vulnerable to external moisture or oxygen, an encapsulation layer ENCAP for preventing external moisture or oxygen from penetrating into the circuit element (particularly, the light emitting device ED) can be disposed on the sub-pixels SP.

The encapsulation layer ENCAP can be formed of one layer or can be formed of multiple layers.

In one embodiment, the touch sensor TS can be disposed on the encapsulation layer ENCAP. For example, the touch sensor TS including a plurality of touch electrodes TE can be formed on the encapsulation layer ENCAP.

During touch sensing, a touch driving signal or a touch sensing signal can be applied to the touch electrode TE. Therefore, during touch sensing, a potential difference is formed between the touch electrode TE and the cathode electrode with the encapsulation layer ENCAP interposed therebetween, thereby forming unnecessary parasitic capacitance. Because this parasitic capacitance can reduce touch sensitivity, in order to reduce the parasitic capacitance, the distance between the touch electrode TE and the cathode electrode can be designed to be equal to or greater than a certain value (e.g., 1 μm) in consideration of the panel thickness, panel manufacturing process, and display performance. To this end, for example, the thickness of the encapsulation layer ENCAP can be designed to be at least 1 μm or more. However, the present disclosure is not limited thereto.

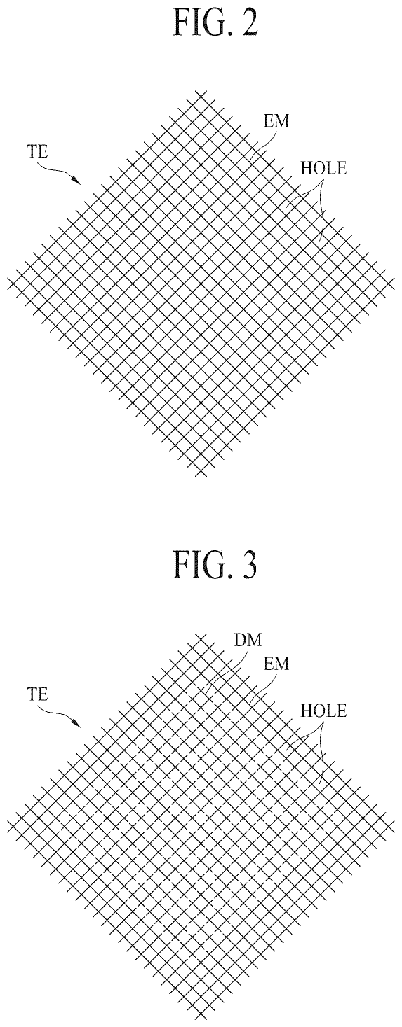

FIG. 2 is a diagram illustrating an example of a touch electrode included in the display device of FIG. 1, and FIG. 3 is a diagram illustrating another example of a touch electrode included in the display device of FIG. 1.

Referring to FIGS. 2 and 3, each touch electrode TE can be an electrode metal EM patterned in a mesh type and having two or more holes HOLE. The electrode metal EM is a portion corresponding to a substantial touch electrode TE, and is a portion where a touch driving signal is applied or a touch sensing signal is sensed.

In FIGS. 2 and 3, the touch electrode TE is illustrated to have a rhombus shape, but this is exemplary, and the shape (layout) of the touch electrode TE is not limited thereto.

In an embodiment, when each touch electrode TE is an electrode metal EM patterned in a mesh type, two or more holes HOLE can exist in the area of the touch electrode TE.

Each of two or more holes HOLE present in each touch electrode TE can correspond to an emitting area of one or more sub-pixels. For example, a plurality of holes HOLE are paths through which light emitted from a plurality of sub-pixels disposed below the plurality of holes HOLE passes upward.

In other words, the electrode metal EM of the touch electrode TE can be disposed on a pixel defining layer by avoiding the emitting area.

Also, as a method of forming multiple touch electrodes TE, after forming the electrode metal EM widely into a mesh type, the electrode metal EM is cut into a predetermined pattern to electrically separate the electrode metals EM, thereby making multiple touch electrodes TE.

The outline shape of the touch electrode TE can be a square such as a diamond shape and a rhombus, or various shapes such as a triangle, a pentagon, or a hexagon.

In one embodiment, as illustrated in FIG. 3, there can be one or more dummy metals DM which are cut off from the mesh-type electrode metal EM in the area of each touch electrode TE.

The electrode metal EM is a portion corresponding to a substantial touch electrode TE and is a portion where a touch driving signal is applied or a touch sensing signal is detected, but the dummy metal DM is a portion where a touch driving signal is not applied and a touch sensing signal is not detected, although it exists within the area of the touch electrode TE. For example, the dummy metal DM can be an electrically floated metal.

Therefore, the electrode metal EM can be electrically connected to the touch driving circuit, but the dummy metal DM is not electrically connected to the touch driving circuit.

For example, in each area of all touch electrodes TE, one or more dummy metals DM can exist in a state of being cut off from the electrode metal EM.

In contrast, one or more dummy metals DM can exist in a state of being cut off from the electrode metal EM only in the area of each touch electrode TE of some of the touch electrodes TE. For example, the dummy metal DM may not exist in the area of some touch electrodes TE.

Also, regarding the role of dummy metal DM, as illustrated in FIG. 2, if one or more dummy metals DM do not exist in the area of the touch electrode TE and only the electrode metal EM exists in a mesh type, a visibility issue showing the outline of the electrode metal EM on the screen can occur.

In contrast, as illustrated in FIG. 3, when one or more dummy metals DM exist in the area of the touch electrode TE, a visibility issues showing the outline of the electrode metal EM on the screen can be prevented.

Furthermore, by adjusting the presence/absence or the number of the dummy metal DM (e.g., dummy metal ratio) for each touch electrode TE, the size of capacitance for each touch electrode TE can be adjusted to improve touch sensitivity.

For example, by cutting some points in the electrode metal EM formed in the area of one touch electrode TE, the cut electrode metal EM can be the dummy metal DM. For example, the electrode metal EM and the dummy metal DM can be the same material formed on the same layer.

The display device according to embodiments of the present disclosure can sense a touch based on a capacitance formed on the touch electrode TE.

The display device according to embodiments of the present disclosure uses a capacitance-based touch sensing method, can sense a touch by using a mutual-capacitance-based touch sensing method, or can sense a touch by using a self-capacitance-based touch sensing method.

In the case of the mutual-capacitance-based touch sensing method, the plurality of touch electrodes TE can be classified into a driving touch electrode (transmission touch electrode) to which a touch driving signal is applied, and a sensing touch electrode (reception touch electrode) which detects a touch sensing signal and forms capacitance with the driving touch electrode.

In the case of such a mutual-capacitance-based touch sensing method, a touch sensing circuit (TSC) can sense the presence or absence of a touch and/or a touch coordinate based on a change in capacitance (mutual-capacitance) between the driving touch electrode and the sensing touch electrode according to the presence or absence of a pointer such as a finger or pen.

In the case of the self-capacitance-based touch sensing method, each touch electrode TE serves as both a driving touch electrode and a sensing touch electrode. For example, the touch sensing circuit applies a touch driving signal to one or more touch electrodes TE, detects a touch sensing signal through the touch electrode TE to which the touch driving signal is applied, and identifies a change in capacitance between a pointer such as a finger or a pen and the touch electrode TE based on the detected touch sensing signal to sense the presence or absence of a touch and/or touch coordinates. In the self-capacitance-based touch sensing method, there is no distinction between the driving touch electrode and the sensing touch electrode.

As described above, the touch screen integrated display device according to embodiments of the present disclosure can sense a touch through the mutual-capacitance-based touch sensing method or can sense a touch through the self-capacitance-based touch sensing method. However, hereinafter, for convenience of description, the touch screen integrated display device performing mutual-capacitance-based touch sensing and having a touch sensor structure for this purpose will be described as an example.

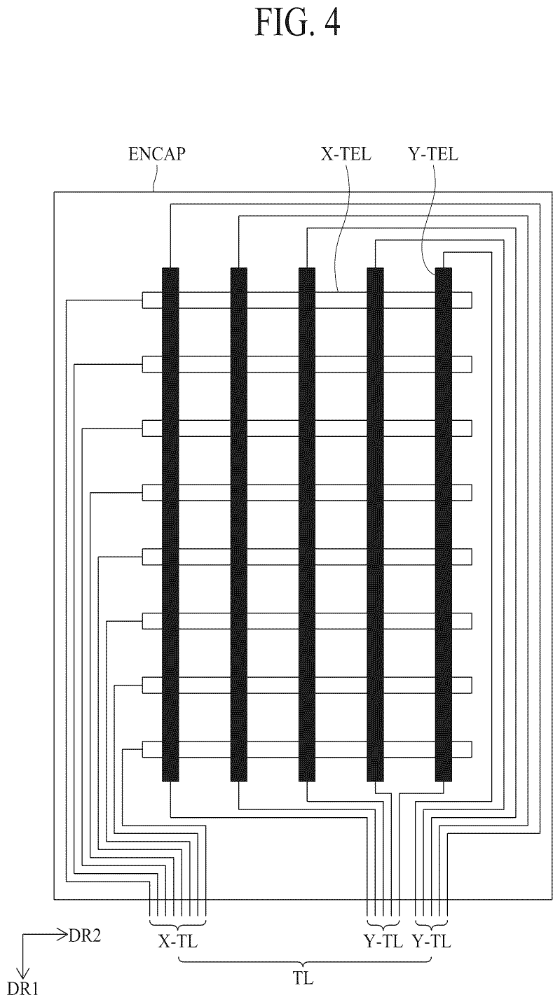

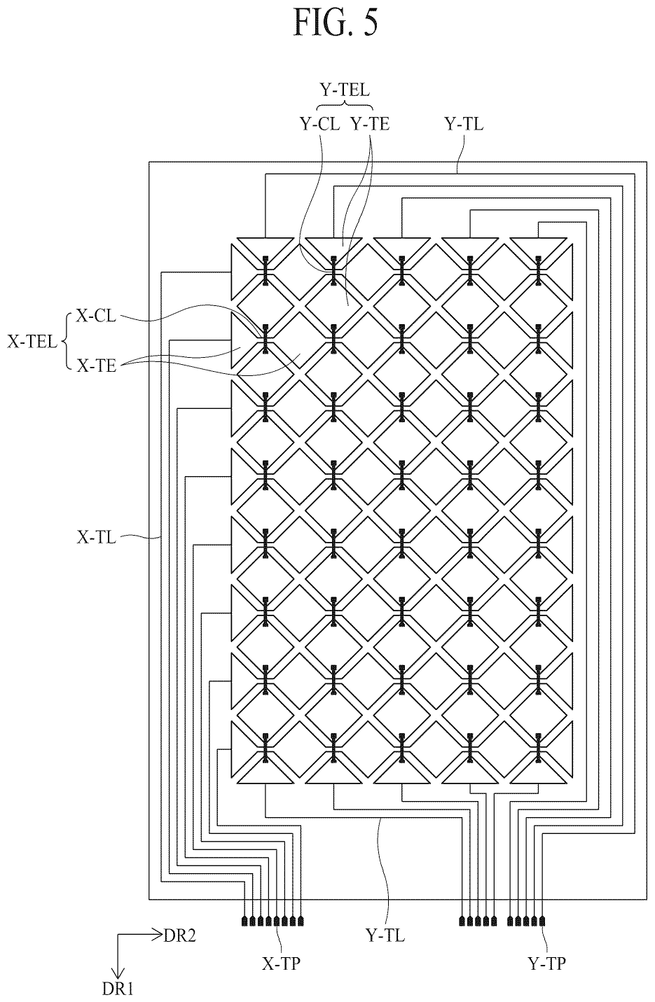

FIG. 4 is a diagram for describing an example of a touch sensor included in the display device of FIG. 1, and FIG. 5 is a diagram illustrating an example in which the touch sensor of FIG. 4 is implemented.

Referring to FIGS. 4 and 5, a touch sensor structure for mutual-capacitance-based touch sensing can include X-touch electrode lines X-TEL and Y-touch electrode lines Y-TEL. Here, the X-touch electrode lines X-TEL and Y-touch electrode lines Y-TEL are disposed on the encapsulation layer ENCAP. Each of the X-touch electrode lines X-TEL can be referred to as a first touch electrode line, and each of the Y-touch electrode lines Y-TEL can be referred to as a second touch electrode line.

The Y-touch electrode lines Y-TEL can extend in a first direction DR1, and the X-touch electrode lines X-TEL can extend in a second direction DR2.

In the present disclosure, the first direction DR1 and the second direction DR2 can be relatively different directions, and for example, the first direction can be an x-axis direction and the second direction can be a y-axis direction. On the contrary, the first direction can be a y-axis direction and the second direction can be an x-axis direction. Also, the first direction and the second direction can be orthogonal to each other or may not be orthogonal to each other. Further, in the present disclosure, as rows and columns are relative, the rows and columns can be changed according to the viewpoint.

Each of the X-touch electrode lines X-TEL can include a plurality of X-touch electrodes X-TE electrically connected to each other. Each of the Y-touch electrode lines Y-TEL can include a plurality of Y-touch electrodes Y-TE electrically connected to each other. The X-touch electrode can be referred to as a first touch electrode, and the Y-touch electrode can be referred to as a second touch electrode.

The X-touch electrode X-TE and the Y-touch electrode Y-TE are electrodes which are included in the touch electrode TE and whose roles (functions) are divided.

For example, the X-touch electrodes X-TE configuring each of the X-touch electrode lines X-TEL can be driving touch electrodes, and the Y-touch electrodes Y-TE configuring each of the Y-touch electrode lines Y-TEL can be sensing touch electrodes. In this case, each of a plurality of X-touch electrode lines X-TEL corresponds to a driving touch electrode line, and each of a plurality of Y-touch electrode lines Y-TEL corresponds to a sensing touch electrode line.

For another example, the X-touch electrode X-TE can be a sensing touch electrode, and the Y-touch electrode Y-TE can be a driving touch electrode. In this case, each of the plurality of X-touch electrode lines X-TEL corresponds to a sensing touch electrode line, and each of the plurality of Y-touch electrode lines Y-TEL corresponds to a driving touch electrode line.

A touch sensor metal for touch sensing can include touch routing lines TL in addition to the X-touch electrode lines X-TEL and Y-touch electrode lines Y-TEL.

The touch routing lines TL can include X-touch routing lines X-TL connected to each of the X-touch electrode lines X-TEL and Y-touch routing lines Y-TL connected to each of the Y-touch electrode lines Y-TEL.

Each of the X-touch electrode lines X-TEL can include X-touch electrodes X-TE disposed in the same row (or column) and one or more X-touch electrode connection lines X-CL electrically connecting the X-touch electrodes X-TE. Here, the X-touch electrode connection line X-CL connecting two adjacent X-touch electrodes X-TE can be a metal integrated with two adjacent X-touch electrodes X-TE (example of FIG. 5) or a metal connected to two adjacent X-touch electrodes X-TE through a contact hole.

Each of the Y-touch electrode lines Y-TEL can include Y-touch electrodes Y-TE disposed in the same column (or row) and one or more Y-touch electrode connection lines Y-CL electrically connecting the Y-touch electrodes Y-TE. Here, the Y-touch electrode connection line Y-CL connecting two adjacent Y-touch electrodes Y-TE can be a metal integrated with two adjacent Y-touch electrodes Y-TE or a metal connected to two adjacent Y-touch electrodes Y-TE through a contact hole (example of FIG. 5).

In the area where the X-touch electrode line X-TEL and the Y-touch electrode line Y-TEL intersect each other (a touch electrode line intersection area), the X-touch electrode connection line X-CL and the Y-touch electrode connection line Y-CL can intersect each other.

In this case, in the area where the X-touch electrode line X-TEL and the Y-touch electrode line Y-TEL intersect each other (a touch electrode line intersection area), the X-touch electrode connection line X-CL and the Y-touch electrode connection line Y-CL can intersect each other.

As such, when the X-touch electrode connection line X-CL and the Y-touch electrode connection line Y-CL intersect in the touch electrode line intersection area, the X-touch electrode connection line X-CL and the Y-touch electrode connection line Y-CL should be disposed on different layers.

Accordingly, in order to arrange the X-touch electrode line X-TEL and the Y-touch electrode line Y-TEL to intersect each other, the X-touch electrode X-TE, the X-touch electrode connection line X-CL, the Y-touch electrode Y-TE, the Y-touch electrode line Y-TEL, and the Y-touch electrode connection line Y-CL can be disposed on two or more layers. The X-touch electrode connection line can be referred to as a first touch electrode connection line, and the Y-touch electrode connection line can be referred to as a second touch electrode connection line.

Each of the X-touch electrode lines X-TEL is electrically connected to a corresponding X-touch pad X-TP through one or more X-touch routing lines X-TL. For example, among a plurality of X-touch electrodes X-TE included in one X-touch electrode line X-TEL, a X-touch electrode X-TE disposed at the outermost part is electrically connected to a corresponding X-touch pad X-TP through the X-touch routing line X-TL.

Each of the Y-touch electrode lines Y-TEL is electrically connected to a corresponding Y-touch pad Y-TP through one or more Y-touch routing lines Y-TL. For example, among a plurality of Y-touch electrodes Y-TE included in one Y-touch electrode line Y-TEL, a Y-touch electrode Y-TE disposed at the outermost part is electrically connected to a corresponding Y-touch pad Y-TP through the Y-touch routing line Y-TL.

The X-touch electrode line X-TEL and the Y-touch electrode line Y-TEL can be disposed on the encapsulation layer ENCAP. For example, the X-touch electrode X-TE and the X-touch electrode connection line X-CL configuring the X-touch electrode line X-TEL can be disposed on the encapsulation layer ENCAP.

The Y-touch electrode Y-TE and the Y-touch electrode connection line Y-CL configuring the Y-touch electrode line Y-TEL can be disposed on the encapsulation layer ENCAP.

Each of the X-touch routing lines X-TL electrically connected to the X-touch electrode line X-TEL can be disposed on the encapsulation layer ENCAP and extend to an area where the encapsulation layer ENCAP is not present so as to be electrically connected to the X-touch pad X-TP. Each of the Y-touch routing lines Y-TL electrically connected to the Y-touch electrode line Y-TEL can be disposed on the encapsulation layer ENCAP and extend to an area where the encapsulation layer ENCAP is not present so as to be electrically connected to the Y-touch pad Y-TP.

Here, the encapsulation layer ENCAP can be located within an active area, and in some cases, can extend to a non-active area.

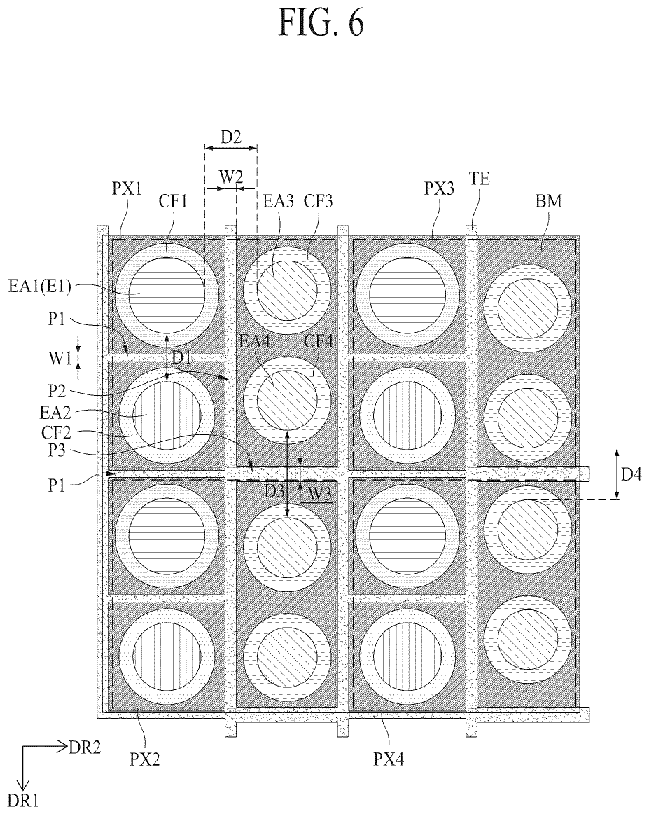

FIG. 6 is a plan view illustrating an example of an arrangement of a touch electrode included in the display device of FIG. 1.

Referring to FIG. 6, a mesh-type touch electrode TE can be disposed to avoid light emitting areas EA1, EA2, EA3, and EA4. The touch electrode TE may have a mesh structure non-overlapping the first to fourth light emitting areas EA1, EA2, EA3, and EA4.

For convenience of description, FIG. 6, regardless of the stacking up and down order, conceptually shows the shape in which the light emitting areas EA1, EA2, EA3, and EA4 of pixels PX1, PX2, PX3, and PX4, the touch electrode TE, a black matrix BM, and color filters CF1, CF2, CF3, and CF4 are arranged on a plane.

In an embodiment, each of the first light emitting area EA1, the second light emitting area EA2, the third light emitting area EA3, and the fourth light emitting area EA4 can be defined by the exposed first electrode E1 (e.g., an anode electrode) of each of the light emitting devices. However, this is exemplary, and the definition of the light emitting area is not limited thereto. For example, the light emitting area can also be defined as an area corresponding to each light emitting layer, an opening area of a pixel defining layer, or the like.

In an embodiment, the second light emitting area EA2 can be adjacent to the first light emitting area EA1 in the first direction DR1, and the third light emitting area EA3 can be adjacent to the first light emitting area EA1 in the second direction DR2. The second direction DR2 can be a direction intersecting the first direction DR1. The fourth light emitting area EA4 can be adjacent to the second light emitting area EA2 in the second direction DR2, and can be adjacent to the third light emitting area EA3 in the first direction DR1.

The first light emitting area EA1 can correspond to the first subpixel, and the second light emitting area EA2 can correspond to the second subpixel. The third light emitting area EA3 and the fourth light emitting area EA4 can correspond to the third subpixel. Here, each of the first subpixel, the second subpixel, and the third subpixel can be driven by separate pixel circuit. The third light emitting area EA3 and the fourth light emitting area EA4 can be connected to and controlled by one subpixel circuit.

Further, the first subpixel, the second subpixel, and the third subpixel can configure one pixel PX1, PX2, PX3, or PX4. Here, each of the pixels PX1, PX2, PX3, and PX4 can be a group of subpixels controlled by the same scan signal. Therefore, a plurality of pixels can be arranged in one pixel row. For example, the first pixel PX1 and the third pixel PX3 can be disposed adjacent to each other in the first pixel row, and the second pixel PX2 and the fourth pixel PX4 can be disposed adjacent to each other in the second pixel row.

In an embodiment, the first light emitting area EA1, the second light emitting area EA2, the third light emitting area EA3, and the fourth light emitting area EA4 can have a circular shape in a plan view. For example, a first electrode E1 exposed from the pixel defining layer can have a circular shape.

When a boundary of the light emitting area includes a straight portion, a flare defect in which light is spread in a direction perpendicular to the straight portion in a plane can be recognized. In order to minimize such flare defects, the light emitting areas EA1 to EA4 can be formed to have a circular shape as much as possible.

In an embodiment, at least two of the first light emitting area EA1, the second light emitting area EA2, the third light emitting area EA3, and the fourth light emitting area EA4 can have the different areas. The area of the light emitting area can be determined by reflecting lifespan characteristics of the light emitting device. For example, the effective area of the light emitting area of the light emitting device having a relatively short lifespan can be larger than the area of the light emitting area of the light emitting device having a relatively long lifespan. Accordingly, color characteristics of the display device based on the usage time can be uniformly maintained for a long time.

In an embodiment, the first light emitting area EA1 can emit a first color of light, the second light emitting area EA2 can emit a second color of light, and the third light emitting area EA3 and the fourth light emitting area EA4 can emit a third color of light. For example, the first light emitting area EA1 can emit green light, the second light emitting area EA2 can emit red light, and the third and fourth light emitting areas EA3 and EA4 can emit blue light.

The lifespan of the red light emitting device can be longer than that of the green light emitting device and the blue light emitting device, and the lifespan of the green light emitting device can be longer than that of the blue light emitting device.

In an embodiment, the area of the first light emitting area EA1 having a relatively shorter lifespan can be larger than the area of the second light emitting area EA2 having the longest lifespan. The light emitting area emitting blue light should maintain a circular shape and have a total area larger than the first light emitting area EA1. Accordingly, in an embodiment, the blue light emitting area can be implemented by two circular light emitting areas, for example, the third light emitting area EA3 and the fourth light emitting area EA4.

In other words, a total area of the light emitting areas EA3 and EA4 emitting a third color (e.g., blue) of light in the first pixel PX1 can be greater than an area of the first light emitting area EA1 and greater than an area of the second light emitting area EA2.

According to an embodiment, an area of the third light emitting area EA3 can be substantially the same as an area of the fourth light emitting area EA4. Here, the third light emitting area EA3 and the fourth light emitting area EA4 can emit the same color of light.

A distance between the light emitting areas can be determined based on a limitation of areas of the light emitting areas and a limitation of a space in which the light emitting areas can be disposed. In an embodiment, a distance D1 (hereinafter, referred to as a first distance D1) between the first light emitting area EA1 and the second light emitting area EA2 can be shorter than a distance D2 (hereinafter, referred to as a second distance D2) between the first light emitting area EA1 and the third light emitting area EA3.

Also, the distance D1 between the first light emitting area EA1 and the second light emitting area EA2 can be shorter than a distance D3 (hereinafter, referred to as a third distance D3) between the third light emitting area EA3 and the fourth light emitting area EA4 of pixels adjacent to each other. For example, the third distance D3 can be a distance between the fourth light emitting area EA4 of the first pixel PX1 and the third light emitting area EA3 of the second pixel PX2 adjacent to the first pixel PX1 in the first direction DR1.

According to an embodiment, a distance D4 (hereinafter, referred to as a fourth distance D4) between the fourth light emitting area EA4 of the third pixel PX3 and the third light emitting area EA3 of the fourth pixel PX4 can be different from the third distance D3. For example, an arrangement of light emitting areas in which the fourth distance D4 is shorter than the third distance D3 can be designed. In this case, distances between the third light emitting area EA3 and the fourth light emitting area EA4 in the pixels PX1, PX2, PX3, and PX4 can be substantially the same.

A touch electrode TE including an electrode metal can be disposed on the light emitting devices, and a black matrix BM having an opening portion can be disposed on the touch electrode TE. The black matrix BM may cover the entire touch electrode TE. The black matrix BM can prevent color mixing between adjacent subpixels and/or light emitting areas. An area in which the black matrix BM is disposed can be a non-light emitting area.

The black matrix BM can include opening portions overlapping each of the first to fourth light emitting areas EA1, EA2, EA3, and EA4. An area of each of the opening portions can be greater than an area of each of the first to fourth light emitting areas EA1, EA2, EA3, and EA4 corresponding thereto. For example, the black matrix BM can be formed to be spaced apart from the first to fourth light emitting areas EA1, EA2, EA3, and EA4 by a predetermined interval. Accordingly, a range in which light output from the first to fourth light emitting areas EA1, EA2, EA3, and EA4 is shielded by the black matrix BM can be reduced, and a viewing angle can be improved.

Color filters CF1, CF2, CF3, and CF4 can be filled in the opening portions of the black matrix BM. The first color filter CF1 can overlap the first light emitting area EA1 and cover the entire first light emitting area EA1. The second color filter CF2 can overlap the second light emitting area EA2 and cover the entire second light emitting area EA2. The third color filter CF3 can overlap the third light emitting area EA3 and cover the entire third light emitting area EA3. The fourth color filter CF4 can overlap the fourth light emitting area EA4 and cover the entire fourth light emitting area EA4.

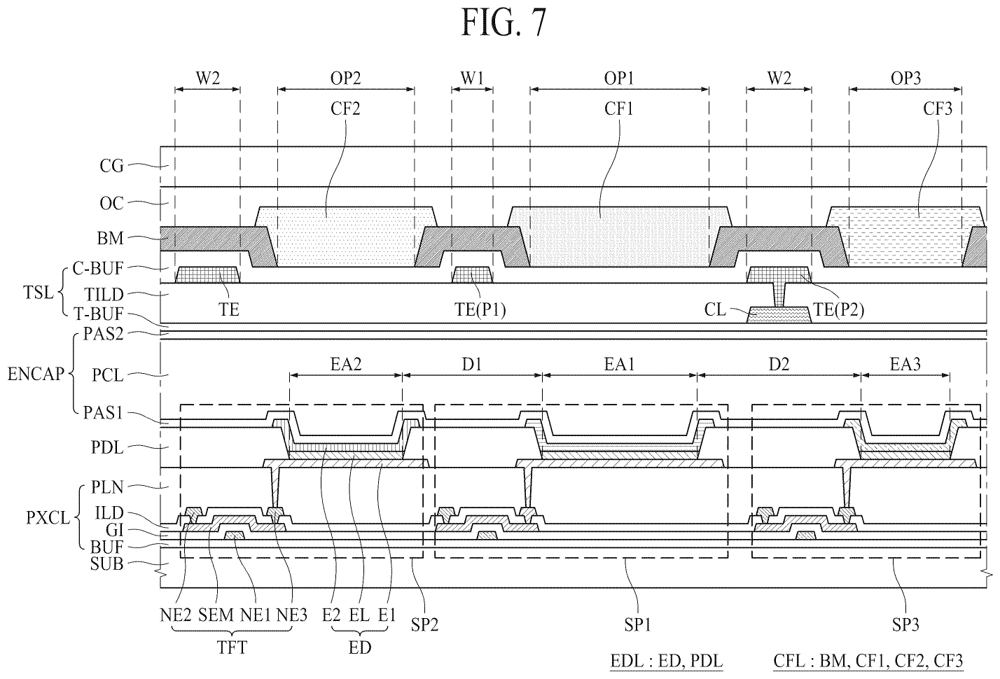

For example, it can be understood that the patterns representing the first to fourth light emitting areas EA1, EA2, EA3, and EA4 in FIG. 6 overlap the first to fourth color filters CF1, CF2, CF3, and CF4, as shown in FIG. 7.

In an embodiment, each of the first to fourth color filters CF1, CF2, CF3, and CF4 can have an area larger than each of the first to fourth light emitting areas EA1, EA2, EA3, and EA4. A viewing angle can increase due to the above-described arrangement structure of the color filters CF1, CF2, CF3, and CF4 and the black matrix BM.

According to an embodiment, some of the first to fourth color filters CF1, CF2, CF3, and CF4 can overlap the black matrix BM. Each of the first to fourth color filters CF1, CF2, CF3, and CF4 may have a circular shape in a plan view.

The first color filter CF1 can correspond to the first color, the second color filter CF2 can correspond to the second color, and the third and fourth color filters CF3 and CF4 can correspond to the third color.

In this way, the planar shape, area, and position of the light emitting area can be determined in consideration of the flare defect, the lifespan of the light emitting device, and the viewing angle, and accordingly, black matrix BM of various widths can be formed between the light emitting areas.

The mesh-type touch electrode TE can be disposed to overlap the black matrix BM so as not to affect image visibility.

The touch electrode TE can be designed to have various widths based on an arrangement position. The touch electrode TE can include a first portion P1 extending in the second direction DR2 between the first light emitting area EA1 and the second light emitting area EA2, and a second portion P2 extending in the first direction DR1 between the first light emitting area EA1 and the third light emitting area EA3. The second portion P2 can also extend between the second light emitting area EA2 and the fourth light emitting area EA4.

The average width of the first portion P1 can be different from the average width of the second portion P2. The width of the first portion P1 can be defined in the first direction DR1, and the width of the second portion P2 can be defined in the second direction DR2.

Because the first distance D1 is shorter than the second distance D2, the minimum width of the black matrix BM between the first light emitting area EA1 and the second light emitting area EA2 is smaller than the minimum width of the black matrix BM between the first light emitting area EA1 and the third light emitting area EA3. For example, the minimum width of the black matrix BM between the first light emitting area EA1 and the second light emitting area EA2 can be about 9 μm.

Also, in order for the touch electrode TE not to affect visibility, the black matrix BM covering the touch electrode TE should have a margin with respect to the touch electrode TE, for example, the line width of the touch electrode TE. For example, the black matrix BM should overlap the touch electrode TE with a margin of about 3 μm or more in both directions with respect to the touch electrode TE, for example, the line width of the touch electrode TE.

In an embodiment of the present disclosure, because the minimum width of the black matrix between the first light emitting area EA1 and the second light emitting area EA2 is reduced to about 9 μm, the width of the first portion P1 of the touch electrode TE can be designed to be about 3 μm for visibility.

However, when the line width of the touch electrode TE becomes thinner (or reduced), the resistance and RC delay of the touch electrode can increase, and the touch sensing performance can be deteriorated. Therefore, in order to improve the viewing angle by reducing the width of the black matrix BM and minimize the deterioration of the touch sensing performance, the line width of the touch electrode TE can have a different size depending on the position.

In an embodiment, the first portion P1 can have a substantially uniform first width W1, and the second portion P2 can have a substantially uniform second width W2. The second width W2 can be greater than the first width W1. For example, the second width W2 can be about 5 μm, and the first width W1 can be about 3 μm. Accordingly, a minimum margin between the black matrix BM and the first portion P1 of the touch electrode TE can be secured.

The touch electrode TE can further include a third portion P3 which extends in the second direction DR2 from the intersection of the first portion P1 and the second portion P2 and is adjacent to the fourth light emitting area EA4. The third portion P3 can be disposed between the fourth light emitting area EA4 of the first pixel PX1 and the third light emitting area EA3 of the second pixel PX2.

In an embodiment, the width (hereinafter, referred to as a third width W3) of the third portion P3 (e.g., the width in the first direction DR1) can be greater than the first width W1. For example, the width of the third portion P3 can be substantially the same as the second width W2.

The first and third portions P1 and P3 of the touch electrode TE are continuous in the second direction DR2 and can be repeated alternately. Therefore, the line width of the touch electrode TE extending in the second direction DR2 can vary between the first and third widths W1 and W3.

According to an embodiment, as illustrated in FIG. 6, the touch electrode TE cannot be disposed between the third light emitting area EA3 and the fourth light emitting area EA4 in one pixel.

As described above, the display device according to the embodiments of the present disclosure has a structure in which color filters CF1, CF2, CF3, and CF4 are disposed on the encapsulation layer and the touch electrode TE can includes circular light emitting areas EA1 to EA4 to minimize flare defects, and can include a structure (e.g., a pull-back structure) to minimize the area in which the black matrix BM is disposed between the light emitting areas in order to maximize the viewing angle. In addition, by forming the line width of the touch electrode TE of some areas thinner than that of other areas in response to the various widths of the black matrix BM, touch sensing performance and viewing angles can be sufficiently secured at the same time.

FIG. 7 is a cross-sectional view illustrating an example of a display device including the touch electrode of FIG. 6.

Referring to FIGS. 1, 6, and 7, the display device 10 can include a substrate SUB, a pixel circuit layer PXCL, a light emitting device layer EDL, an encapsulation layer ENCAP, a touch sensor layer TSL, and a color filter layer CFL.

The substrate SUB is a supporting member for supporting other components of the display device 10, and can be formed of an insulating material. For example, the substrate SUB can be formed of glass or resin. Also, the substrate SUB can be formed of a plastic such as a polymer or polyimide (PI), or can be formed of a material having flexibility.

A buffer layer BUF can be disposed on the substrate SUB. The buffer layer BUF can be formed as a single layer or multiple layers consisting of at least one of an inorganic material and an organic material to prevent the light emitting device ED from being damaged from impurities such as alkali ions flowing out of the substrate SUB in a subsequent process.

For example, the inorganic material can include any one of a silicon oxide (SiOx), a silicon nitride (SiNx), and a silicon oxynitride (SiON). The organic material can include any one of polyimide, benzocyclobutene series resin, and polyacrylate, and examples of the polyacrylate can include photoacryl.

The pixel circuit layer PXCL including a transistor TFT can be disposed on an active area of the substrate SUB. For example, the transistor TFT includes a first node electrode NE1 corresponding to a gate electrode, a second node electrode NE2 corresponding to a source electrode or a drain electrode, a third node electrode NE3 corresponding to a drain electrode or a source electrode, and a semiconductor layer SEM.

The first node electrode NE1 and the semiconductor layer SEM can overlap each other with the gate insulating layer GI interposed therebetween. The second node electrode NE2 can be formed on the insulating layer ILD to be in contact with one side of the semiconductor layer SEM, and the third node electrode NE3 can be formed on the insulating layer ILD to be in contact with the other side of the semiconductor layer SEM. The insulating layer ILD can be made of a single layer formed of an inorganic material or multiple layers formed of different inorganic materials. For example, the insulating layer ILD can be made of a single layer formed of any one of a silicon oxide (SiOx), a silicon nitride (SiNx), and a silicon oxynitride (SiON), or multiple layers thereof.

A planarization layer PLN can be disposed on the insulating layer ILD. The planarization layer PLN is for protecting a lower structure while mitigating a step difference of the lower structure, and can be formed of an organic material. For example, the organic material can include any one of polyimide, benzocyclobutene-based resin, and polyacrylate. Examples of the polyacrylate can include photoacryl.

FIG. 7 shows a bottom gate structure in which a gate electrode is disposed below a source/drain electrode, but the present disclosure is not limited thereto. For example, the transistor TFT can have a top gate structure in which a gate electrode is disposed on a source/drain electrode.

Referring to FIG. 7, the light emitting device layer EDL can be disposed on the pixel circuit layer PXCL. The light emitting device layer EDL can include a light emitting device ED and a bank PDL (also referred to as a pixel defining layer).

The light emitting device ED can include a first electrode E1, a light emitting layer EL, and a second electrode E2.

The first electrode E1 can be an anode electrode, and is electrically connected to the third node electrode NE3 of the first transistor TFT through a pixel contact hole penetrating the planarization layer PLN.

A bank PDL exposing the first electrode E1 can be formed on the planarization layer PLN. The bank PDL has an opening portion, and the first electrode E1 can be exposed through the opening portion. The opening portion of the bank PDL can be an area defining the light emitting areas EA1, EA2, and EA3. For example, the first electrode E1 exposed by the bank PDL can have a circular shape as illustrated in FIG. 6.

In one embodiment, the bank PDL is a black bank (or black pixel defining layer) having black, and can prevent optical interference and color mixing between adjacent light emitting areas. The bank PDL can be formed by mixing a black material with a base resin. The base resin can be at least one selected from epoxy-based resin, acrylate-based resin, siloxane-based resin, and polyimide, but is not limited thereto. Also, the black material can be formed of any one of a black-based pigment and a black-based dye.

The light emitting layer EL is formed on the first electrode E1 of a light emitting area defined by the bank PDL. The light emitting layer EL is formed by stacking a hole-related layer, a light emitting layer EL, and an electron-related layer on the first electrode E1 in order or in reverse order.

The light emitting layer EL of the first subpixel SP1 can emit a first color of light, the light emitting layer EL of the second subpixel SP2 can emit a second color of light, and the light emitting layer EL of the third subpixel SP3 can emit a third color of light.

The second electrode E2 can be disposed to face the first electrode E1 with the light emitting layer EL interposed therebetween. For example, the second electrode E2 can be commonly disposed on the first to third subpixels SP1, SP2, and SP3, but the present invention is not limited thereto.

The encapsulation layer ENCAP can be disposed on the light emitting device layer EDL.

The encapsulation layer ENCAP blocks the penetration of external moisture or oxygen into the light emitting device ED which is vulnerable to external moisture or oxygen. The encapsulation layer ENCAP can be formed of one layer or can be formed of a plurality of layers.

For example, the encapsulation layer ENCAP can have a structure in which a first inorganic encapsulation layer PAS1, an organic encapsulation layer PCL, and a second inorganic encapsulation layer PAS2 are sequentially stacked. The encapsulation layer ENCAP can further include one or more organic encapsulation layers and/or at least one inorganic encapsulation layer.

The first inorganic encapsulation layer PAS1 and the second inorganic encapsulation layer PAS2 can be formed of an inorganic insulating material capable of low-temperature deposition such as silicon nitride (SiNx), silicon oxide (SiOx), silicon oxynitride (SiON), or aluminum oxide (Al₂O₃).

The organic encapsulation layer PCL can be formed of an organic insulating material such as acrylic resin, epoxy resin, polyimide, polyethylene, or silicon oxycarbon (SiOC).

The touch sensor layer TSL can be disposed on the encapsulation layer ENCAP. In an embodiment, the touch sensor layer TSL can include a touch buffer layer T-BUF, a connection electrode CL, a touch insulating layer TILD, a touch electrode TE, and a protective layer C-BUF.

The touch buffer layer T-BUF is formed to prevent damage to the encapsulation layer ENCAP and the light emitting device ED in the process of forming the touch sensor layer TSL. The touch buffer layer T-BUF can be formed of an inorganic material such as silicon nitride (SiNx), silicon oxide (SiOx), aluminum oxide (AlOx), or the like, but is not limited thereto.

The connection electrode CL can be disposed on the touch buffer layer T-BUF. The connection electrode CL can serve as a bridge connecting some of the touch electrodes TE. The connection electrode CL can be formed to overlap a portion of the upper touch electrode TE.

The touch insulating layer TILD is disposed on the touch buffer layer T-BUF and can cover the connection electrode. The touch insulating layer TILD can be an organic insulating layer. However, the present disclosure is not limited thereto. The touch insulating layer TILD can be an inorganic insulating layer or have a structure in which an organic insulating layer is stacked on an inorganic insulating layer.

The touch electrode TE can be disposed on the touch insulating layer TILD. The touch electrode TE can include an opaque conductive material. The touch electrode TE can be formed to overlap the bank PDL by avoiding the light emitting areas EA1, EA2, and EA3. The width of the touch electrode TE can be determined according to the width of the black matrix BM on the top.

The protective layer C-BUF can be disposed on the touch electrode TE. The protective layer C-BUF can be formed to prevent damage to the touch sensor layer TSL in the process of forming the color filter and the black matrix BM.

The protective layer C-BUF can be an inorganic insulating layer. For example, the protective layer C-BUF can include an inorganic material such as silicon nitride (SiNx), silicon oxide (SiOx), aluminum oxide (AlOx), or the like.

The color filter layer CFL can be disposed on the protective layer C-BUF. The color filter layer CFL can include a first color filter CF1, a second color filter CF2, a third color filter CF3, and a black matrix BM.

The black matrix BM can be formed by mixing a black material with a base resin. The base resin can be at least one selected from an epoxy-based resin, an acrylate-based resin, a siloxane-based resin, and a polyimide, but is not limited thereto. Also, the black material can be formed of either a black-based pigment or a black-based dye.

The black matrix BM can overlap the touch electrode TE. When viewed in a plan view, the black matrix BM can be disposed to be spaced apart from the light emitting area EA. For example, a first opening portion OP1 of the black matrix BM can overlap the first light emitting area EA1 and can be formed wider than the first light emitting area EA1. Likewise, a second opening portion OP2 of the black matrix BM can overlap the second light emitting area EA2 and can be formed wider than the second light emitting area EA2. A third opening portion OP3 of the black matrix BM can overlap the third light emitting area EA3 and can be formed wider than the third light emitting area EA3.

The first distance D1 between the first light emitting area EA1 and the second light emitting area EA2 can be less than the second distance D2 between the first light emitting area EA1 and the third light emitting area EA3. Accordingly, the width of the black matrix BM between the first light emitting area EA1 and the second light emitting area EA2 can be less than the width of the black matrix between the first light emitting area EA1 and the third light emitting area EA3, and the first width W1 of the first portion P1 of the touch electrode TE can be less than the second width W2 of the second portion P2.

As such, the line width of the touch electrode TE can be determined based on the width of the black matrix BM in the non-emitting area.

A color filter can be filled in each of the opening portions OP1, OP2, and OP3 of the black matrix BM.

The first color filter CF1 can fill the first opening portion OP1. The first color filter CF1 can cover a part of the black matrix BM. The first color filter CF1 can correspond to the first color.

The second color filter CF2 can fill the second opening portion OP2. The second color filter CF2 can cover a part of the black matrix BM. The second color filter CF2 can correspond to the second color.

The third color filter CF3 can fill the third opening portion OP3. The third color filter CF3 can cover a part of the black matrix BM. The third color filter CF3 can correspond to the third color.

The color filters CF1, CF2, and CF3 and the black matrix BM can be directly formed on the protective layer C-BUF. The protective layer C-BUF may be in direct contact with the touch electrode TE, the black matrix BM, and the color filters CF1, CF2, and CF3. An area of the first color filter CF1 corresponding to the first light emitting area EA1, an area of the second color filter CF2 corresponding to the second light emitting area EA2, and an area of the third color filter CF3 corresponding to the third light emitting area EA3 may be different from each other.

An overcoat layer OC can be disposed on the color filter layer CFL, and a cover glass CG can be disposed on the overcoat layer OC.

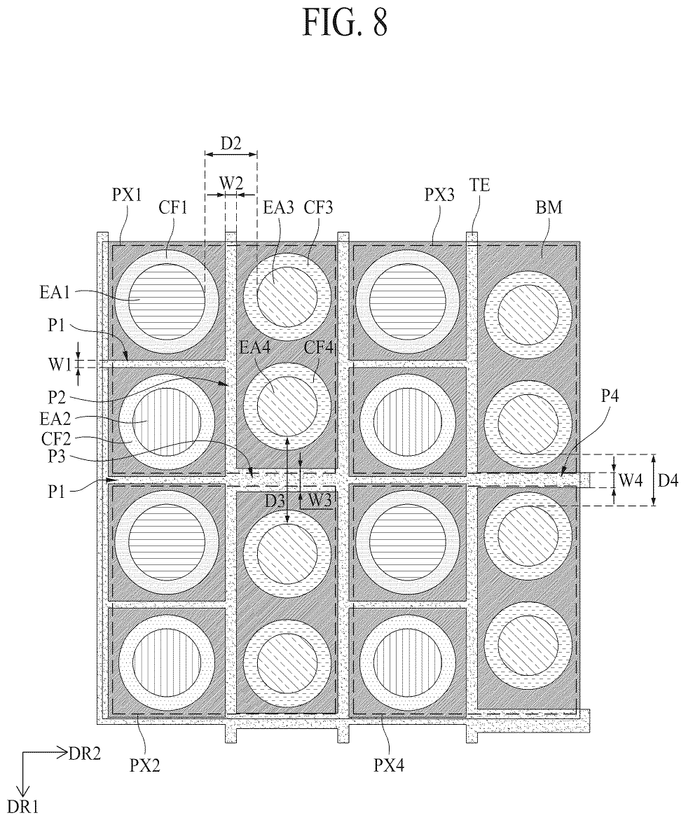

FIG. 8 is a plan view illustrating another example of an arrangement of a touch electrode included in the display device of FIG. 1.

In the following description with reference to FIG. 8, details which are the same as or similar to details described with reference to FIGS. 6 and 7 will be omitted or may be briefly provided.

Referring to FIG. 8, the mesh-type touch electrode TE can be disposed to overlap the black matrix BM in the upper part.

In an embodiment, the width W3 of the third portion P3 of the touch electrode TE between the fourth light emitting area EA4 of the first pixel PX1 and the third light emitting area EA3 of the second pixel PX2 can be different from the width W4 of the fourth portion P4 of the touch electrode TE between the fourth light emitting area EA4 of the third pixel PX3 and the third light emitting area EA3 of the fourth pixel PX4.

As described above, the distance D3 between the fourth light emitting area EA4 of the first pixel PX1 and the third light emitting area EA3 of the second pixel PX2 can be different from the distance D4 between the fourth light emitting area EA4 of the third pixel PX3 and the third light emitting area EA3 of the fourth pixel PX4. For example, the third distance D3 can be greater than the fourth distance D4. Therefore, the width of the black matrix BM between the fourth light emitting area EA4 of the first pixel PX1 and the third light emitting area EA3 of the second pixel PX2 can be greater than the width of the black matrix BM between the fourth light emitting area EA4 of the third pixel PX3 and the third light emitting area EA3 of the fourth pixel PX4.

The width W3 of the third portion P3 of the touch electrode TE can be greater than the width W4 of the fourth portion P4. Also, the width W3 of the third portion P3 of the touch electrode TE can be greater than the width W2 of the second portion P2.

Accordingly, RC delay or the like of the touch electrode TE formed to have a relatively thin width in the first portion P1 can be compensated due to the thickness of the third portion P3. Accordingly, while the viewing angle is secured, the touch sensing performance can be additionally improved.

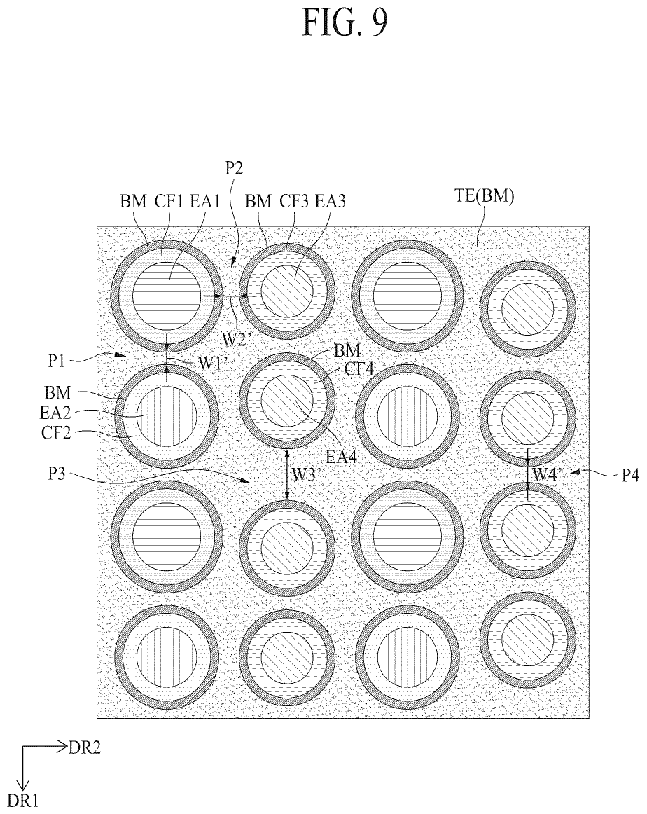

FIG. 9 is a plan view illustrating another example of an arrangement of a touch electrode included in the display device of FIG. 1.

In the following description with reference to FIG. 9, details which are the same as or similar to details described with reference to FIGS. 6 and 7 will be omitted or may be briefly provided.

Referring to FIG. 9, the mesh-type touch electrode TE can be disposed to overlap the black matrix BM in the upper part. For example, a black matrix BM can overlap the touch electrode TE in all areas representing the touch electrode TE in FIG. 9.

In an embodiment, the touch electrode TE can be disposed along the planar shape of the black matrix BM. For example, the black matrix BM can be formed with a uniform margin with respect to the touch electrode TE. Therefore, in a plan view, a portion of the black matrix BM non-overlapping with the touch electrode TE can have a circular ring shape. In this case, the circular ring shape can have a uniform width. For example, the circular ring shape can have a width of 3 μm or more. The remaining portion of the black matrix BM can overlap the touch electrode TE. For example, in FIG. 9, a black matrix BM can be disposed on an upper portion of an area in which the touch electrode TE is disposed.

The width of the first portion P1 of the touch electrode TE in the first direction DR1 can vary. Likewise, the width of the second portion P2 of the touch electrode TE in the second direction DR2 and the width of the third portion P3 in the first direction DR1 can vary.

For example, the minimum width W1′ of the first portion P1 of the touch electrode TE can be different from the minimum width W2′ of the second portion P2 of the touch electrode TE. Also, the minimum width W3′ of the third portion P3 of the touch electrode TE3 and the minimum width W4′ of the fourth portion P4 can be different from the minimum width W1′ of the first portion P1 and the minimum width W2′ of the second portion P2.

In the display device according to the present embodiment, an electrode area of the touch sensor TE is secured as much as possible, so that touch sensing performance can be additionally improved.

A display device according to embodiments of the present disclosure has a structure in which a color filter is disposed on an encapsulation layer and a touch electrode can include circular light emitting areas to minimize flare defects, and can include a structure (e.g., a pull-back structure) to minimize an area in which a black matrix is disposed between the light emitting areas to maximize the viewing angle. In addition, by forming the line width of the touch electrode in a portion of areas thinner than that of other areas in response to the various widths of the black matrix, touch sensing performance and viewing angle can be sufficiently secured at the same time.

However, the effects of this invention are not limited to the above-described effects, and can be variously extended without departing from the spirit and scope of this invention.

The above-described feature, structure, and effect of the present disclosure are included in at least one embodiment of the present disclosure, but are not limited to only one embodiment. Furthermore, the feature, structure, and effect described in at least one embodiment of the present disclosure can be implemented through combination or modification of other embodiments by those skilled in the art. Therefore, content associated with the combination and modification should be construed as being within the scope of the present disclosure.

It will be apparent to those skilled in the art that various modifications and variations can be made in the present disclosure without departing from the spirit or scope of the disclosures. Thus, it is intended that the present disclosure covers the modifications and variations of this disclosure provided they come within the scope of the present disclosure.

What is claimed is:

1. A display device comprising:
a light emitting device layer including a first light emitting area, a second light emitting area disposed adjacent to the first light emitting area and extending in a first direction, a third light emitting area disposed adjacent to the first light emitting area and extending in a second direction, and a fourth light emitting area disposed adjacent to the third light emitting area and extending in the first direction;
an encapsulation layer covering the light emitting device layer;
a touch electrode disposed on the encapsulation layer and having a mesh structure non-overlapping the first to fourth light emitting areas;
a black matrix including opening portions overlapping the first to fourth light emitting areas, disposed on the touch electrode, and covering the entire touch electrode; and
color filters filled in each of the opening portions and having a larger area than each of the first to fourth light emitting areas,
wherein an average width of a first portion of the touch electrode extending in the second direction between the first light emitting area and the second light emitting area is different from an average width of a second portion of the touch electrode extending in the first direction between the first light emitting area and the third light emitting area.

2. The display device of claim 1, wherein the first light emitting area emits a first color of light, the second light emitting area emits a second color of light, and the third light emitting area and the fourth light emitting area emit a third color of light.

3. The display device of claim 2, wherein each of the first to fourth light emitting areas has a circular shape in a plan view.

4. The display device of claim 2, wherein a distance between the first light emitting area and the second light emitting area is shorter than a distance between the first light emitting area and the third light emitting area,
the first portion has a first width, and
the second portion has a second width greater than the first width.

5. The display device of claim 4, wherein the touch electrode further includes a third portion which extends in the second direction from an intersection of the first portion and the second portion, and is adjacent to the fourth light emitting area, and
a width of the third portion is greater than the second width.

6. The display device of claim 4, wherein the first to fourth light emitting areas configure a pixel, and
a distance between a fourth light emitting area of a first pixel and a third light emitting area of a second pixel adjacent to the first pixel in the first direction is greater than a distance between the first light emitting area and the third light emitting area.

7. The display device of claim 3, wherein a portion of the black matrix that is non-overlapping with the touch electrode has a circular ring shape in a plan view, and
the circular ring shape has a uniform width.

8. The display device of claim 7, wherein a width of the first portion of the touch electrode extending in the first direction and a width of the second portion of the touch electrode extending in the second direction are variable.

9. The display device of claim 8, wherein a minimum width of the first portion of the touch electrode is different from a minimum width of the second portion of the touch electrode.

10. The display device of claim 8, wherein the touch electrode further includes a third portion disposed between the third light emitting area and the fourth light emitting area and having a variable width in the first direction, and
a minimum width of the third portion is different from the minimum width of the first portion and the minimum width of the second portion.

11. The display device of claim 3, wherein the light emitting device layer includes:
first electrodes corresponding to the first to fourth light emitting areas, each of the first electrodes having a circular shape in a plan view;
a bank covering a portion of the first electrodes and disposed between the first electrodes;
a light emitting layer disposed on the first electrodes; and
a second electrode disposed on the light emitting layer,
wherein the bank is black.

12. The display device of claim 11, wherein each of the color filters has a circular shape in a plan view.

13. The display device of claim 1, further comprising a protective layer disposed between the touch electrode and the black matrix.

14. The display device of claim 13, wherein the protective layer is in direct contact with the touch electrode, the black matrix, and the color filters, and
the protective layer includes an inorganic insulating material.

15. The display device of claim 13, wherein each of the color filters covers a portion of the black matrix.

16. The display device of claim 3, wherein an area of a first color filter corresponding to the first light emitting area, an area of a second color filter corresponding to the second light emitting area, and an area of a third color filter corresponding to the third light emitting area are different from each other.

17. The display device of claim 3, wherein an area of each of the opening portions of the black matrix is larger than an area of each of the first to fourth light emitting areas corresponding to the opening portions.

18. The display device of claim 1, wherein a minimum width of the black matrix between the first light emitting area and the second light emitting area is smaller than a minimum width of the black matrix between the first light emitting area and the third light emitting area.

19. The display device of claim 4, wherein the touch electrode further includes a third portion which extends in the second direction from an intersection of the first portion and the second portion, and is adjacent to the fourth light emitting area, and
a width of the third portion is greater than the first width and substantially the same as the second width.

20. The display device of claim 5, wherein the first and third portions of the touch electrode are continuous in the second direction and are repeated alternately.
